(19) United States
(12) Patent Application Publication
(10) Pub. No.: US 2026/0215264 A1
(43) Pub. Date: Jul. 23, 2026

(54) SEMICONDUCTOR PACKAGE AND METHOD OF MANUFACTURING THE SAME

(71) Applicant: KOOLMICRO INC., Daejeon (KR)

(72) Inventor: Jiwon IM, Yongin-si (KR)

(21) Appl. No.: 19/347,535

(22) Filed: Oct. 1, 2025

(30) Foreign Application Priority Data
Jan. 23, 2025 (KR) 10-2025-0010192
Aug. 28, 2025 (KR) 10-2025-0121399

(51) Int. Cl. H10W 40/40; H10W 40/60; H10W 76/47; H10W 90/00; H10W 72/00; H10W 80/00

(52) U.S. Cl. CPC H10W 40/40; H10W 40/613; H10W 76/47; H10W 90/00; H10W 72/0198; H10W 80/312; H10W 80/327; H10W 90/734; H10W 90/794

(57) ABSTRACT

An embodiment of the present disclosure provides a semiconductor package, in which a plurality of semiconductor chips having different heights are mounted, the semiconductor package including a fluid flow structure bonded directly to a first semiconductor chip among the plurality of semiconductor chips and formed to allow a fluid to flow therethrough, in which a second semiconductor chip, which is greater in thickness than the first semiconductor chip among the plurality of semiconductor chips, is mounted on the semiconductor package. According to the semiconductor package and the method of manufacturing the same according to the embodiment of the present disclosure, it is possible to simultaneously and efficiently cool the plurality of semiconductor chips formed on the semiconductor package and having different heights.

### CROSS-REFERENCE TO RELATED APPLICATION

This application claims priority to and the benefit of Korean Patent Application No. 10-2025-0121399, filed on August 28, 2025, the disclosures of which is incorporated herein by reference in its entirety.

### BACKGROUND

### FIELD

The present disclosure relates to a semiconductor package and a method of manufacturing the same, and more particularly, to a semiconductor package structure capable of efficiently cooling a semiconductor chip in a semiconductor package by utilizing a microchannel, and a method of manufacturing the same.

### DESCRIPTION OF THE RELATED ART

In the advancement of modern industrial technologies, a recent key topic is the control of heat. For example, the amount of calculation performed by semiconductor chips increases, the number of chip processes decreases, and the amount of heat generation (power density) per unit area increases. As the amount of heat generation per unit area increases, the air-cooled method with a low heat transfer rate in the related art has a limitation in controlling the amount of heat generation of the semiconductor chip. In particular, the air-cooled type cooling method requires a large-scale air-conditioning facility and has a problem with noise, spatial utilization, and the like. In order to solve this problem, a cooling method utilizing a liquid cooling structure has been actively introduced recently.

In particular, with increases in high-performance computation (HPC) and artificial intelligence (AI) workloads, 2.5D/3D packaging, in which a logic chip (graphics processing unit (GPU)/central processing unit (CPU)) and a high-bandwidth memory (HBM) are closely disposed, has become common. In this structure, the logic chip and an HBM stack are different in geometric shape and stacking height, which inevitably causes a variation in height of an upper surface of the chip even though the logic chip and the HBM stack are disposed on the same plane.

In the related art, a configuration is widely used in which an entire upper surface of a package is covered by a flat cold plate, and a thermal interface material (TIM) is interposed between the package and the cold plate to reduce thermal resistance. However, the presence of the variation in height of the upper surface of the chip causes a problem in which a thickness of the thermal interface material significantly varies depending on regions between the flat cold plate and the chip, which causes a problem in that heat transfer efficiency deteriorates.

### Document of Related Art

### Patent Document

(Patent Document 1) Korean Patent No. 10-2659553

### SUMMARY

The present disclosure has been made in an effort to solve the above-mentioned problem, and an object of the present disclosure is to provide a semiconductor package including a fluid flow structure capable of effectively cooling a semiconductor chip by means of a liquid.

More specifically, an object of the present disclosure is to prevent a deterioration in heat exchange efficiency caused by a configuration in which a plurality of chips having different heights are disposed in a single semiconductor package.

An embodiment of the present disclosure provides a semiconductor package, in which a plurality of semiconductor chips having different heights are mounted, the semiconductor package including a fluid flow structure bonded directly to a first semiconductor chip among the plurality of semiconductor chips and formed to allow a fluid to flow therethrough, in which a second semiconductor chip, which is greater in thickness than the first semiconductor chip among the plurality of semiconductor chips, is mounted on the semiconductor package.

In the semiconductor package according to the embodiment of the present disclosure, the fluid flow structure may include: a microchannel part including a plurality of microchannels through which the fluid flows, the microchannel part bonded directly to the first semiconductor chip; and a manifold part formed on the microchannel part and configured to distribute the fluid to the microchannels and collect the fluid.

The semiconductor package according to the embodiment of the present disclosure may include a lid formed to cover the plurality of semiconductor chips, in which the fluid flow structure communicates with a fluid port formed in the lid and is disposed in a space between the lid and the first semiconductor chip.

In the semiconductor package according to the embodiment of the present disclosure, the manifold part may include: an inlet port through which the fluid is supplied to the microchannels; and an outlet port through which the fluid is discharged from the microchannels.

In the semiconductor package according to the embodiment of the present disclosure, the fluid port may include a first fluid port including: a first fluid supply port configured to supply the fluid to the inlet port; and a first fluid discharge port configured to collect the fluid from the outlet port.

The semiconductor package according to the embodiment of the present disclosure may include a sealing member formed between the lid and the manifold part and configured to prevent the fluid from leaking and prevent the fluid, which is introduced into the inlet port, and the fluid, which is discharged from the outlet port, from being mixed.

In the semiconductor package according to the embodiment of the present disclosure, the sealing member may include: a first sealing member formed to correspond to an outermost side of the manifold and configured to prevent the fluid from leaking; and a second sealing member formed to correspond to a boundary between the first fluid supply port and the first fluid discharge port and configured to prevent the fluid, which is introduced into the inlet port, and the fluid, which is discharged from the outlet port, from being mixed.

In the semiconductor package according to the embodiment of the present disclosure, the fluid flow structure may be disposed in a space defined by a difference in height between the first semiconductor chip and the second semiconductor chip.

In the semiconductor package according to the embodiment of the present disclosure, the fluid port may include a second fluid port formed to correspond to the second semiconductor chip to cool the second semiconductor chip, and the second fluid port may include: a second fluid supply port through which the fluid is introduced; and a second fluid discharge port through which the fluid is discharged.

In the semiconductor package according to the embodiment of the present disclosure, a thermal interface material (TIM) layer may be formed between the lid and the second semiconductor chip.

In the semiconductor package according to the embodiment of the present disclosure, the lid and the second semiconductor chip may be coupled by direct bonding.

The semiconductor package according to the embodiment of the present disclosure may include a second fluid flow structure bonded directly to the second semiconductor chip and formed to be in fluid communication with the second fluid port.

The semiconductor package according to the embodiment of the present disclosure may further include: a stiffener formed on a periphery of a packaging substrate of the semiconductor package; and a fastening member configured to couple the lid and the stiffener.

Another embodiment of the present disclosure provides a method of manufacturing a semiconductor package in which a plurality of semiconductor chips having different heights are mounted, the method including: a first bonding step of bonding a microchannel part directly to a rear surface of a first semiconductor chip among a plurality of semiconductor chips in a fluid flow structure including the microchannel part including a plurality of microchannels through which a fluid flows, and a manifold part formed on the microchannel part and configured to distribute the fluid to the microchannels and collect the fluid; and a second bonding step of flip-chip bonding an upper surface of the first semiconductor chip onto an interposer and mounting a second semiconductor chip, among the plurality of semiconductor chips, on the interposer.

In the method of manufacturing the semiconductor package according to the embodiment of the present disclosure, the first bonding step may include bonding the microchannel part of the fluid flow structure directly to the rear surface of the first semiconductor chip that is completely diced.

In the method of manufacturing the semiconductor package according to the embodiment of the present disclosure, the first bonding step may include bonding the microchannel part of the fluid flow structure directly onto a first semiconductor wafer before the first semiconductor chip is diced and then dicing the first semiconductor wafer.

In the method of manufacturing the semiconductor package according to the embodiment of the present disclosure, a method of directly bonding the first semiconductor wafer and the fluid flow structure in the first bonding step may couple the first semiconductor wafer and a fluid flow structure wafer, on which the plurality of fluid flow structures are formed, by a wafer-on-wafer method.

In the method of manufacturing the semiconductor package according to the embodiment of the present disclosure, a method of directly bonding the first semiconductor wafer and the fluid flow structure in the first bonding step may couple the first semiconductor wafer and the fluid flow structure by a chip-on-wafer method of bonding the fluid flow structure directly to the first semiconductor wafer.

In the method of manufacturing the semiconductor package according to the embodiment of the present disclosure, the second bonding step may include: a stage step of disposing the plurality of semiconductor chips on an interposer wafer; an interposer bonding step of flip-chip bonding the upper surface of the first semiconductor to the interposer wafer and mounting the second semiconductor on the interposer wafer; a wafer level molding step of covering the upper surface of the interposer wafer and the plurality of semiconductor chips with an epoxy molding compound (EMC); a mold grinding step of grinding or flattening the epoxy molding compound and exposing the manifold part of the fluid flow structure; and a step of dividing the interposer wafer into individual interposer packages by dicing the interposer wafer.

The method of manufacturing the semiconductor package according to the embodiment of the present disclosure may further include: a step of mounting the individual interposer packages on a packaging substrate; and a step of coupling the lid and a stiffener, which is formed on a periphery of the substrate of the semiconductor package, by means of a fastening member.

According to the semiconductor package and the method of manufacturing the same according to the embodiment of the present disclosure, it is possible to simultaneously and efficiently cool the plurality of semiconductor chips formed on the semiconductor package and having different heights.

In particular, the plurality of semiconductor chips may be logic chips, such as CPUs and GPUs, or memory chips, such as HBMs, and the liquid cooling structure according to the embodiment of the present disclosure may be designed to prevent a deterioration in cooling efficiency caused by a difference in height between the plurality of semiconductor chips.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF THE DRAWING

The above and other aspects, features and other advantages of the present disclosure will be more clearly understood from the following detailed description taken in conjunction with the accompanying drawings, in which:

FIGS. 1A to 1C are conceptual views illustrating a semiconductor package in the related art;

FIG. 2 is a conceptual view illustrating a semiconductor package according to an embodiment of the present disclosure;

FIG. 3 is a conceptual view illustrating a fluid flow structure and a lid of the semiconductor package according to the embodiment of the present disclosure;

FIGS. 4A to 4C are views sequentially illustrating a first bonding step of a method of manufacturing a semiconductor package according to the embodiment of the present disclosure;

FIGS. 5A to 5E are views sequentially illustrating a second bonding step of the method of manufacturing a semiconductor package according to the embodiment of the present disclosure; and

FIG. 6 is a view illustrating a final step of the method of manufacturing a semiconductor package according to the embodiment of the present disclosure.

### DETAILED DESCRIPTION

Hereinafter, various embodiments of the present disclosure disclosed herein will be described with reference to the accompanying drawings. The description of the embodiments is not intended to limit the present disclosure to the particular embodiments, but it should be understood that the present disclosure is to cover all modifications, equivalents, and/or alternatives of the embodiments of the present disclosure. In connection with the description of the drawings, similar reference numerals may be used for the similar constituent elements.

As used herein, the terms "have," "may have," "include," or "may include" indicate the existence of a feature (e.g., a number, function, operation, or a constituent element such as a part) and do not exclude the existence of other features.

As used herein, the terms "A or B," "at least one of A and/or B," or "one or more of A and/or B" may include all possible combinations of A and B listed together. For example, "A or B," "at least one of A and B," "at least one of A or B" may indicate all of (1) including at least one A, (2) including at least one B, or (3) including at least one A and at least one B.

As used herein, the terms "configured (or set) to" may be interchangeably used with the terms "suitable for," "having the capacity to," "designed to," "adapted to," "made to," or "capable of" depending on circumstances. The term "configured (or set) to" does not necessarily mean only "specifically designed to."

The terms used in the present document are used to just describe a specific embodiment and do not intend to limit the scope of another embodiment. Singular expressions may include plural expressions unless clearly described as different meanings in the context. The terms used herein, including technical or scientific terms, may have the same meaning as commonly understood by those skilled in the art disclosed in the present document. The terms such as those defined in commonly used dictionaries may be interpreted as having meanings identical or similar to meanings in the context of related technologies and should not be interpreted as ideal or excessively formal meanings unless explicitly defined in the present document. In some instances, the terms defined in the present document should not be interpreted to exclude the embodiments disclosed in the present document.

Therefore, the configurations of the embodiments disclosed in the present specification are just the best preferred exemplary embodiments of the present disclosure and do not represent all the technical spirit of the present disclosure. Accordingly, it should be appreciated that various equivalents and modified examples capable of substituting the embodiments may be made at the time of filing the present application.

Throughout the specification, unless explicitly described to the contrary, the word "comprise" and variations such as "comprises" or "comprising", will be understood to imply the inclusion of stated elements but not the exclusion of any other elements.

Other objects, particular advantages, and novel features of the present disclosure described in the present specification will be more clearly understood from the following detailed description and the exemplary embodiments with reference to the accompanying drawings. In giving reference numerals to constituent elements of the respective drawings in the present specification, it should be noted that the same constituent elements will be designated by the same reference numerals, if possible, even though the constituent elements are illustrated in different drawings. In addition, the terms "one surface," "the other surface," "first," "second," and the like are used to distinguish one constituent element from another constituent element, and the constituent element is not limited by the terms described above. In the following description of the present disclosure, the specific descriptions of well-known related technologies will be omitted when it is determined that the specific descriptions may unnecessarily obscure the subject matter of the present disclosure.

Hereinafter, the embodiments of the present disclosure will be described in detail with reference to the accompanying drawings, and the same reference numerals refer to the same members.

The present disclosure has been achieved through research conducted to solve the aforementioned problems via the research project described below.

a. Project Number: AICT-03-TB1

b. Ministry Name: Gyeonggi Province

c. Name of Project Management (Specialized) Organization: Advanced Institute of Convergence Technology

d. Research Program Name: Semiconductor Technology Development Project Utilizing the Gyeonggi Province Testbed

e. Research Project Name: Development of Semiconductor Chip Bonding Technology Using Self-Induction Based on Testbed Utilization

f. Research Performing Institution: KOOLMICRO Co., Ltd.

g. Research Period: May 1, 2023 – December 31, 2025

Hereinafter, a semiconductor package 1 according to the present disclosure will be described with reference to the drawings.

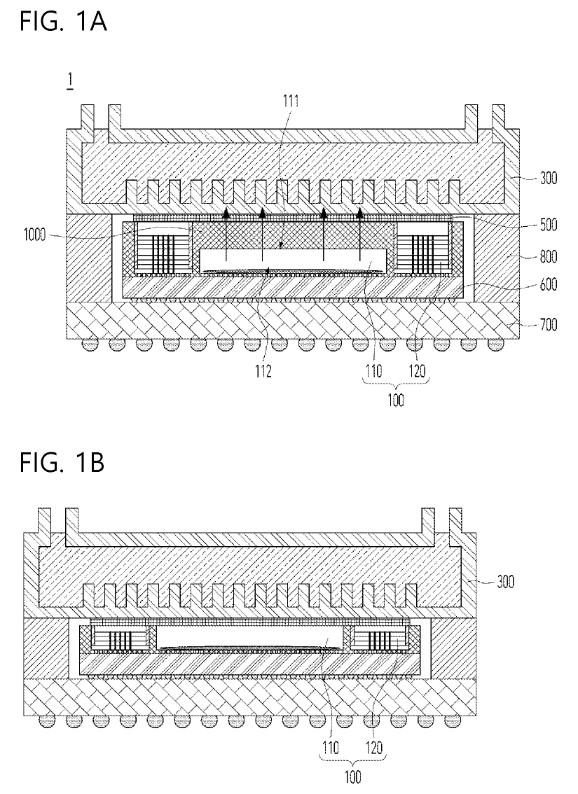

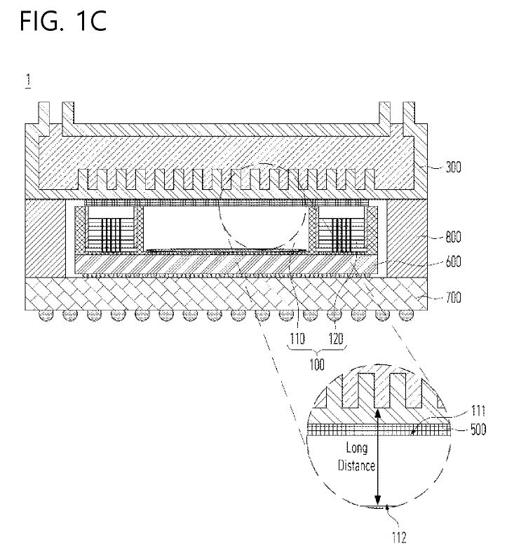

FIGS. 1A to 1C are conceptual views illustrating a semiconductor package in the related art.

In the related art, because a cold plate is flat, the cold plate cannot come into contact with a semiconductor chip having a low height when the cold plate is used to cool a semiconductor package in which different types of semiconductor chips are mounted. With reference to FIG. 1A, it can be seen that because of a difference in height between a first semiconductor chip 110 and a second semiconductor chip 120, an epoxy molding compound (EMC) is formed in a separation space between the first semiconductor chip 110 and a lid 300. In this case, because heat exchange is performed between the lid 300 and the first semiconductor chip 110 through the epoxy molding compound with low thermal conductivity, a problem occurs in that a temperature of the first semiconductor chip 110 increases because thermal conduction is not sufficiently achieved. In particular, a heat source generated in the semiconductor chip is a front side at which a transistor is provided, and the first semiconductor chip 110 is flip-chip bonded to an interposer 600, such that a front surface 112 of the first semiconductor chip 110 faces the interposer 600. The flip-chip bonding is performed by bonding the front surface of the semiconductor chip by inverting the front side of the semiconductor chip downward. In case that only the first semiconductor chip 110 is disposed in the semiconductor package, a heat transfer length decreases as a thickness of the first semiconductor chip 110 decreases, such that thermal resistance decreases. Therefore, a temperature of the first semiconductor chip 110 decreases. However, in case that a plurality of chips with different heights are disposed in the semiconductor package, an epoxy molding compound is inevitably formed on a rear surface 111 of the first semiconductor chip 110 in order to equalize the height. In this case, the heat exchange with the cold plate needs to be performed by means of the rear surface 111 of the first semiconductor chip 110. However, because the heat transfer length increases by a thickness of the first semiconductor chip 110 and a thickness of the epoxy molding compound, a temperature of the first semiconductor chip 110 inevitably increases in the structure illustrated in FIG. 1A.

There are two methods of bringing the flat cold plate and all the chips into contact with one another simultaneously. As illustrated in FIG. 1B, a first method is a method of reducing a thickness of the second semiconductor chip 120. In this case, a low height is implemented by reducing the number of stacked DRAMs of a high-bandwidth memory (HBM) that is one of the types of second semiconductor chips 120. When the height of the second semiconductor chip 120 decreases as described above, the number of stacked DRAMs is small, which causes a problem in that a capacity of the memory decreases, and performance of the semiconductor package deteriorates.

As illustrated in FIG. 1C, a second method is a method of increasing a thickness of the first semiconductor chip 110 to bring the first semiconductor chip 110 and the cold plate into contact with each other. However, even in this case, because a thickness of a logic chip, which is one of the types of first semiconductor chips 110, is excessively great, and vertical thermal resistance increases. As a result, this method cannot efficiently cool the first semiconductor chip 110.

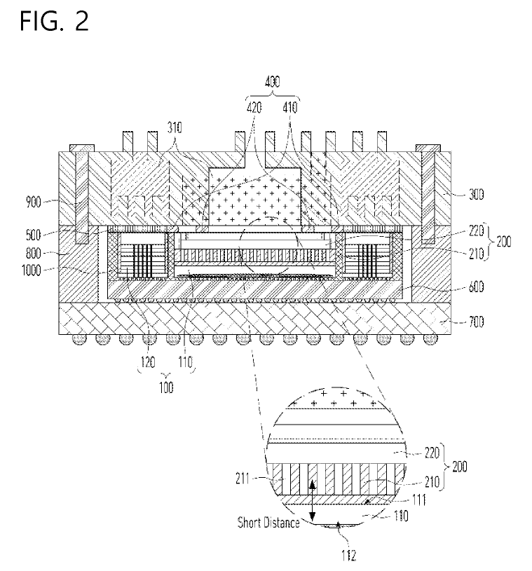

FIG. 2 is a conceptual view illustrating the semiconductor package 1 according to the embodiment of the present disclosure.

The semiconductor package 1 according to the embodiment of the present disclosure is the semiconductor package 1 in which a plurality of semiconductor chips 100 having different heights are mounted. The semiconductor package 1 includes a fluid flow structure 200 bonded directly to a first semiconductor chip 110 among the plurality of semiconductor chips 100 and formed to allow a fluid to flow therethrough, in which a second semiconductor chip 120, which is greater in thickness than the first semiconductor chip 110 among the plurality of semiconductor chips 100, is mounted in the semiconductor package 100.

The plurality of semiconductor chips 100 of the semiconductor package 1 according to the embodiment of the present disclosure includes the first semiconductor chip 110 and the second semiconductor chip 120. In this case, the first semiconductor chip 110 may be a logic chip such as a CPU/GPU. However, the present disclosure is not limited thereto. The first semiconductor chip 110 may be formed as various chips such as an AI Chip, a DPU, and the like. The second semiconductor chip 120 may be the HBM. However, the present disclosure is not limited thereto. The second semiconductor chip 120 may be provided as various memory chips, other logic chip, passive elements, or the like. The semiconductor package 1 according to the embodiment of the present disclosure is structured to prevent the temperature of the first semiconductor chip 110 from being increased by the configuration in which the second semiconductor chip 120 is greater in thickness than the first semiconductor chip 110.

As illustrated in FIG. 2, the semiconductor package 1 according to the embodiment of the present disclosure includes the fluid flow structure 200. The fluid flow structure 200 is formed to allow the fluid to flow therethrough and configured to cool the semiconductor chip 100 by utilizing a liquid cooling method. The fluid flow structure 200 is bonded to a rear surface 111 of the first semiconductor chip 110 by direct bonding. In this case, the term "direct bonding" refers to a technology of forming a chemical or metallurgical bond by precisely aligning two junction surfaces flattened, cleaned, and activated without using an intermediate layer such as a thermal interface material, bonding agent, solder, microbump, or underfill, and then applying pressure and/or heat treatment, thereby bonding the junction surfaces in a state in which an interface thickness is substantially zero. For example, the "direct bonding" may include Si-Si fusion bonding, SiO-SiO₂ fusion bonding, Cu-Cu direct bonding, and hybrid bonding in which oxide direct bonding and metal bonding are performed in combination. However, the present disclosure is not limited thereto.

In the semiconductor package 1 according to the embodiment of the present disclosure, the fluid flow structure 200 may include a microchannel part 210 including a plurality of microchannels 211 through which the fluid flows, the microchannel part 210 being bonded directly to the first semiconductor chip 110, and a manifold part 220 formed on the microchannel part 210 and configured to distribute the fluid to the microchannels 211 and collect the fluid.

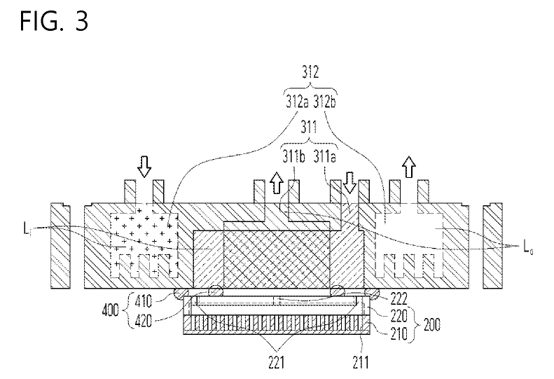

As illustrated in FIGS. 2 and 3, the fluid flow structure 200 of the semiconductor package 1 according to the embodiment of the present disclosure may include the microchannel part 210 and the manifold part 220.

The microchannel part 210 includes the plurality of microchannels 211, and a fluid L flows to the microchannels 211. Because the microchannel part 210 is bonded directly to the first semiconductor chip 110, the microchannel part 210 may cool the first semiconductor chip 110 by directly receiving heat from the first semiconductor chip 110. The first semiconductor chip 110 may be cooled by liquid cooling by means of the fluid L flowing in the microchannel part 210.

The manifold part 220 is configured to distribute the fluid to the microchannels 211 and collect the fluid, and the manifold part 220 is formed on the microchannel part 210.

The semiconductor package 1 according to the embodiment of the present disclosure includes the lid 300 formed to cover the plurality of semiconductor chips 100, and the fluid flow structure 200 communicates with a fluid port 310 formed in the lid 300 and is disposed in a space between the lid 300 and the first semiconductor chip 110.

As illustrated in FIGS. 2 and 3, the semiconductor package 1 according to the embodiment of the present disclosure may include the lid 300 formed to cover the plurality of semiconductor chips 100. The fluid port 310, through which the fluid L is introduced or discharged, is formed in the lid 300, and the fluid port 310 and the fluid flow structure 200 communicate with each other so that the fluid may flow to the microchannel 211.

In the semiconductor package 1 according to the embodiment of the present disclosure, the manifold part 220 may include an inlet port 221 through which the fluid is supplied to the microchannels 211, and an outlet port 222 through which the fluid is discharged from the microchannels 211.

In the semiconductor package 1 according to the embodiment of the present disclosure, the fluid port 310 may include a first fluid port 311 including a first fluid supply port 311a configured to supply the fluid to the inlet port 221, and a first fluid discharge port 311b configured to collect the fluid from the outlet port 222.

The manifold part 220 of the semiconductor package 1 according to the embodiment of the present disclosure may include the inlet port 221 and the outlet port 222. Further, the fluid port 310 of the semiconductor package 1 according to the embodiment of the present disclosure may include the first fluid port 311 including the first fluid supply port 311a configured to supply the fluid to the inlet port 221, and the first fluid discharge port 311b configured to collect the fluid from the outlet port 222. As illustrated in FIG. 3, it can be seen that the inlet ports 221 of the manifold part 220 of the present disclosure are formed at two opposite sides of the manifold part 220, and the outlet port 222 is formed at a center of the manifold part 220. Therefore, an inflow fluid Lᵢ introduced into the manifold part 220 is introduced into an outer periphery of the manifold part 220, and an outflow fluid Lₒ discharged from the manifold part 220 may be discharged from the center of the manifold part 220.

The fluid port 310 of the semiconductor package 1 according to the embodiment of the present disclosure may include the first fluid port 311. The first fluid port 311 may include the first fluid supply port 311a and the first fluid discharge port 311b. The first fluid supply port 311a serves to supply the inflow fluid Lᵢ to the inlet port 221, and the first fluid discharge port 311b serves to collect the outflow fluid Lₒ from the outlet port 222 and discharge the outflow fluid Lₒ. As illustrated in FIG. 3, it can be seen that the inlet port 221 and the first fluid supply port 311a are formed at positions corresponding to each other, and the outlet port 222 and the first fluid discharge port 311b are formed at positions corresponding to each other.

The semiconductor package 1 according to the embodiment of the present disclosure may include a sealing member 400 formed between the lid 300 and the manifold part 220 and configured to prevent leakage of the fluid and prevent the fluid Lᵢ, which is introduced into the inlet port 221, and the fluid Lₒ, which is discharged from the outlet port 222, from being mixed.

In the semiconductor package 1 according to the embodiment of the present disclosure, the sealing member 400 may include a first sealing member 410 formed to correspond to an outermost side of the manifold 220 and configured to prevent the fluid from leaking, and a second sealing member 420 formed to correspond to a boundary between the first fluid supply port 311a and the first fluid discharge port 311b and configured to prevent the fluid Lᵢ, which is introduced into the inlet port 221, and the fluid Lₒ, which is discharged from the outlet port 222, from being mixed.

As illustrated in FIGS. 2 and 3, the semiconductor package 1 according to the embodiment of the present disclosure may further include the sealing member 400. The sealing member 400 may be formed between the lid 300 and the manifold part 220. This is intended to seal a space between the lid 300 and the manifold part 220 spaced apart from each other and to set a movement route for the fluid. In particular, the first sealing member 410 may be formed to correspond to the outermost side of the manifold part 220 and prevent the fluid, which flows between the manifold part 220 and the lid 300, from leaking to the outside. In addition, the second sealing member 420 is formed to correspond to the boundary between the first fluid supply port 311a and the first fluid discharge port 311b in order to serve to prevent the fluid Lᵢ, which is introduced into the inlet port 221, and the fluid Lₒ, which is discharged from the outlet port 222, from being mixed.

That is, in the space between the manifold part 220 and the lid 300, the fluid Lᵢ, which is introduced into the inlet port 221, may flow to a space defined by the first sealing member 410 and the second sealing member 420, and the fluid Lₒ, which is discharged from the outlet port 222, may flow to a space defined by only the first sealing member 410.

In the semiconductor package 1 according to the embodiment of the present disclosure, the fluid flow structure 200 may be disposed in a space defined by a difference in height between the first semiconductor chip 110 and the second semiconductor chip 120.

That is, the fluid flow structure 200 of the semiconductor package 1 according to the embodiment of the present disclosure may be disposed in the space defined by the difference in height between the first semiconductor chip 110 and the second semiconductor chip 120 and utilize the separation space between the flat lid 300 and the first semiconductor chip 110.

In the semiconductor package 1 according to the embodiment of the present disclosure, the fluid port 310 may include a second fluid port 312 formed to correspond to the second semiconductor chip 120 in order to cool the second semiconductor chip 120, and the second fluid port 312 may include a second fluid supply port 312a through which the fluid is introduced, and a second fluid discharge port 312b through which the fluid is discharged.

The fluid port 310 according to the embodiment of the present disclosure may include the second fluid port 312. The second fluid port 312 serves to supply the fluid to cool the second semiconductor chip 120. The second fluid port 312 may include the second fluid supply port 312a and the second fluid discharge port 312b. The inflow fluid Lᵢ may be introduced through the second fluid supply port 312a, and the outflow fluid Lₒ may be discharged through the second fluid discharge port 312b.

A structure, in which the fluids may communicate with each other, may be added between the first fluid supply port 311a and the second fluid supply port 312a. In addition, a structure, in which the fluids may communicate with each other, may be added between the first fluid discharge port 311b and the second fluid discharge port 312b. Therefore, an inlet and an outlet, through which the fluid is supplied from the outside, may be formed only in the second fluid port 312, and an inlet and an outlet may not be formed in the first fluid port 311. Likewise, an inlet and an outlet, through which the fluid is supplied from the outside, may be formed only in the first fluid port 311, and an inlet and an outlet may not be formed in the second fluid port 312. That is, the first fluid port 311 and the second fluid port 312 may have shapes that share the inlet and the outlet through which the fluid is supplied and discharged to the outside.

In the semiconductor package 1 according to the embodiment of the present disclosure, a thermal interface material (TIM) layer may be formed between the lid 300 and the second semiconductor chip 120.

In the semiconductor package 1 according to the embodiment of the present disclosure, the lid 300 and the second semiconductor chip 120 may be coupled by direct bonding.

The semiconductor package 1 according to the embodiment of the present disclosure may include a second fluid flow structure (not illustrated) bonded directly to the second semiconductor chip 120 and formed to be in fluid communication with the second fluid port 312.

In the semiconductor package 1 according to the embodiment of the present disclosure, various heat exchange methods may be applied between the lid 300 and the second semiconductor chip 120. The thermal interface material (TIM) layer may be formed between the lid 300 and the second semiconductor chip 120. The lid 300 and the second semiconductor chip 120 may be coupled by direct bonding and exchange heat with each other. In addition, the separate second fluid flow structure (not illustrated) may be coupled to the second semiconductor chip 120 and formed to be in fluid communication with the second fluid port 312.

A structure, in which the second fluid flow structure and the fluid flow structure 200 are in fluid communication with each other, may be added. Therefore, it is possible to improve the cooling efficiency. In some instances, in another embodiment, the inlet port and the outlet port, through which the fluid is introduced into or discharged from the second fluid flow structure, may not be formed, and the inlet port 221 and the outlet port 222 of the fluid flow structure 200 may be utilized. However, the present disclosure is not limited thereto.

The semiconductor package 1 according to the embodiment of the present disclosure may further include a stiffener 800 formed on a periphery of a packaging substrate 700 of the semiconductor package 1, and fastening members 900 configured to couple the lid 300 and the stiffener 800.

In the semiconductor package 1 according to the embodiment of the present disclosure, the stiffener 800 and the lid 300 are coupled to each other to define an outer housing of the semiconductor package 1. The stiffener 800 and the lid 300 may be coupled by the fastening members 900, and the fastening member 900 may be configured as a clamping member. However, the present disclosure is not limited thereto. The fastening member 900 may be formed as a structure such as a tie-bolt/through-bolt structure or a stud/nut structure.

A method of manufacturing the semiconductor package 1 according to the embodiment of the present disclosure is a method of manufacturing the semiconductor package 1 in which the plurality of semiconductor chips 100 having different heights are mounted, and the method includes a first bonding step of bonding the microchannel part 210 directly to the rear surface 111 of the first semiconductor chip 110 among the plurality of semiconductor chips 100 in the fluid flow structure 200 including the microchannel part 210 including the plurality of microchannels 211 through which the fluid flows, and the manifold part 220 formed on the microchannel part 210 and configured to distribute the fluid to the microchannels 211 and collect the fluid, and a second bonding step of flip-chip bonding the upper surface of the first semiconductor chip 110 onto the interposer 600 and mounting the second semiconductor chip 120, among the plurality of semiconductor chips 100, on the interposer 600.

The method of manufacturing the semiconductor package 1 according to the embodiment of the present disclosure includes the first bonding step and the second bonding step.

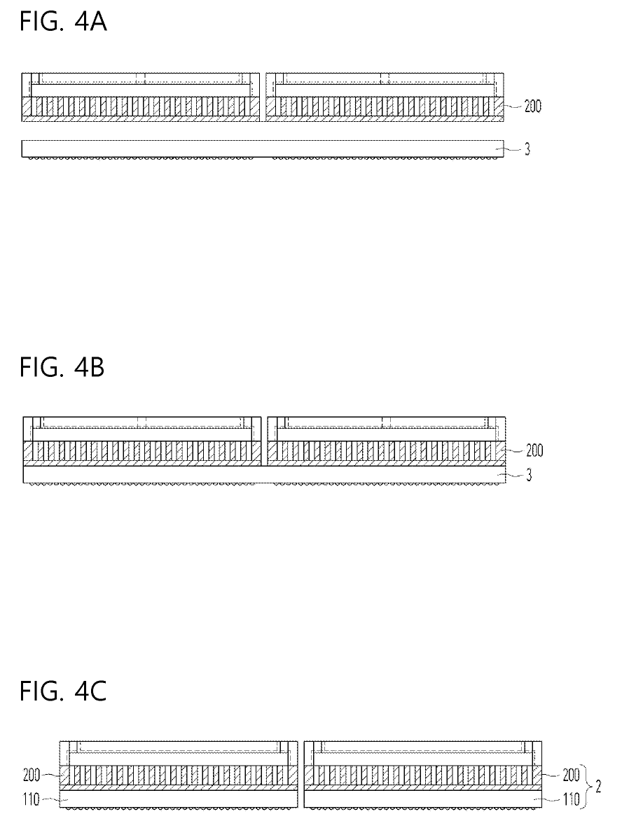

FIGS. 4A to 4C illustrate the first bonding step. The first bonding step refers to a step of bonding the microchannel part 210 of the fluid flow structure 200 directly to the rear surface 111 of the first semiconductor chip 110.

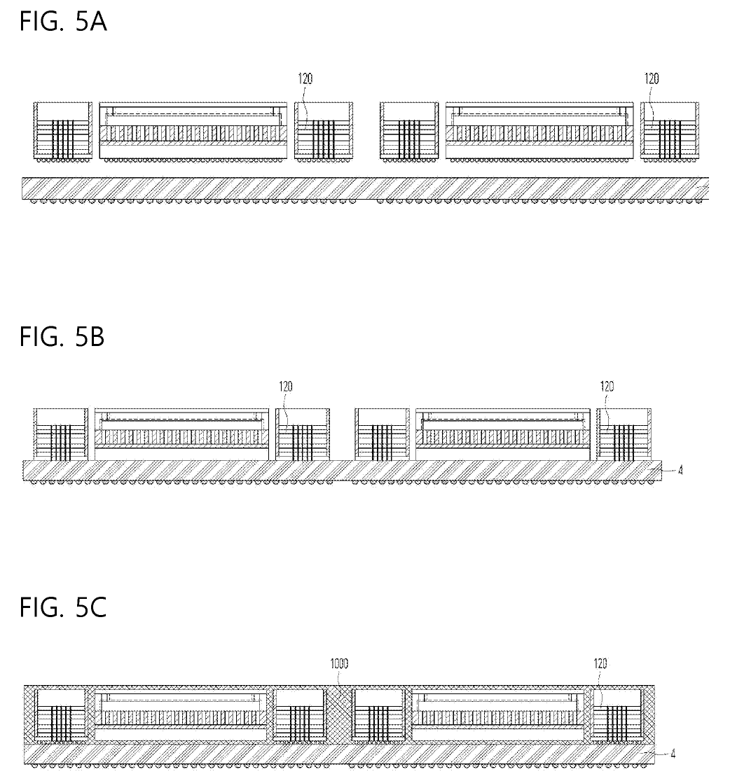

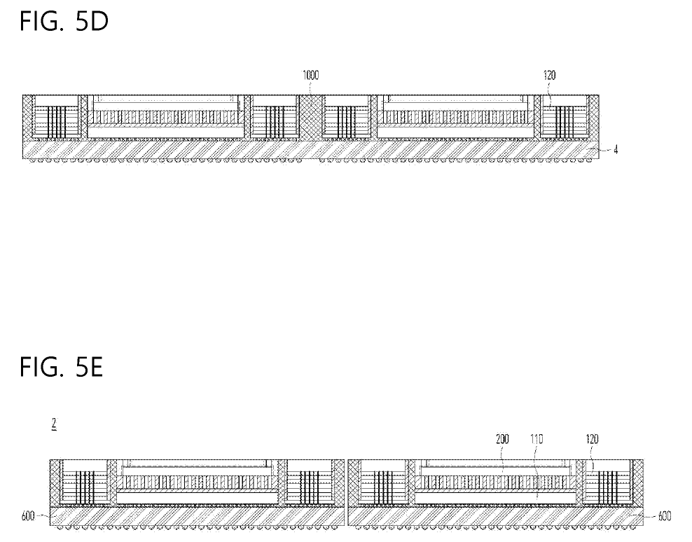

FIGS. 5A to 5E illustrate the second bonding step. The second bonding step refers to a step of forming a separate interposer package 2 by mounting the first semiconductor chip 110 and the second semiconductor chip 120 on the interposer 600.

Various bonding methods may be used for the first bonding step according to the embodiment of the present disclosure.

In the method of manufacturing the semiconductor package 1 according to the embodiment of the present disclosure, the first bonding step may bond the microchannel part 210 of the fluid flow structure 200 directly to the rear surface 111 of the first semiconductor chip 110 that is completely diced.

In the method of manufacturing the semiconductor package 1 according to the embodiment of the present disclosure, the first bonding step may bond the microchannel part 210 of the fluid flow structure 200 directly to a first semiconductor wafer 3 before the first semiconductor chip 110 is diced, and then the first bonding step may dice the first semiconductor wafer 3.

The method of manufacturing the semiconductor package 1 according to the embodiment of the present disclosure may use a chip-on-chip method that dices the first semiconductor wafer 3, on which a circuit of the first semiconductor chip 110 is formed, and individually bonds the first semiconductor chip 110 and the fluid flow structure 200.

In addition, as can be seen in FIGS. 4A to 4C, the method of manufacturing the semiconductor package 1 according to the embodiment of the present disclosure may use a chip-on-wafer bonding method or a wafer-on-wafer method that directly bonds the fluid flow structure 200, before the first semiconductor wafer 3 is diced, and dices the first semiconductor wafer 3.

In the method of manufacturing the semiconductor package according to the embodiment of the present disclosure, the method of directly bonding the first semiconductor wafer 3 and the fluid flow structure 200 in the first bonding step may couple the first semiconductor wafer 3 and the fluid flow structure 200 by a chip-on-wafer method of bonding the fluid flow structure 200 directly to the first semiconductor wafer 3.

In the method of manufacturing the semiconductor package 1 according to the embodiment of the present disclosure, the method of directly bonding the first semiconductor wafer 3 and the fluid flow structure 200 in the first bonding step may couple the first semiconductor wafer 3 and a fluid flow structure wafer, on which the plurality of fluid flow structures 200 are formed, by a wafer-on-wafer method.

FIGS. 4A to 4C illustrate that the chip-on-wafer method is used. Further, although not illustrated in the drawings, the fluid flow structure 200 of the present disclosure may not be individually formed, but the plurality of fluid flow structures 200 may be formed on a single wafer. In this case, the first bonding step may be performed by the wafer-on-wafer method.

FIGS. 5A to 5E illustrate the second bonding step of the method of manufacturing the semiconductor package according to the embodiment of the present disclosure.

In the method of manufacturing the semiconductor package 1 according to the embodiment of the present disclosure, the second bonding step may include a stage step of disposing the plurality of semiconductor chips 1 on an interposer wafer 4, an interposer bonding step of flip-chip bonding the upper surface of the first semiconductor chip 110 onto the interposer wafer 4 and mounting the second semiconductor chip 120 on the interposer wafer 4, a wafer level molding step of covering the upper surface of the interposer wafer 4 and the plurality of semiconductor chips 100 with an epoxy molding compound (EMC) 1000, a mold grinding step of grinding or flattening the epoxy molding compound 1000 and exposing the manifold part 220 of the fluid flow structure 200, and a step of dividing the interposer wafer 4 into the individual interposer packages 2 by dicing the interposer wafer 4.

The second bonding step of the method of manufacturing the semiconductor package 1 according to the embodiment of the present disclosure may include the stage step, the interposer bonding step, the wafer level molding step, the mold grinding step, and the step of dividing the interposer wafer into the individual interposer packages.

As illustrated in FIGS. 5A and 5B, the stage step and the interposer bonding step refer to steps in which the first semiconductor chip 110 is flip-chip bonded to the interposer wafer 4, and the plurality of semiconductor chips 100 and the interposer wafer 4 are aligned and bonded to mount the second semiconductor chip 120 on the interposer wafer 4.

As illustrated in FIG. 5C, the wafer level molding step is performed to form the epoxy molding compound (EMC) 1000 on the semiconductor package 1. This is intended to ensure mechanical rigidity, ensure moisture-proof reliability, and improve process performance.

As illustrated in FIG. 5D, the mold grinding step is performed, and the mold grinding step refers to a step of grinding or flattening the epoxy molding compound 1000 and exposing the manifold part 220 of the fluid flow structure 200.

The inlet port 221 and the outlet port 222 are formed in the manifold part 220 of the fluid flow structure 200, and impurities may be introduced into the inlet port 221 or the outlet port 222 during the semiconductor manufacturing process, which may degrade the performance. Therefore, closure components may be formed in the inlet port 221 and the outlet port 222 to block impurities. In this case, in the mold grinding step, the closure component may also be ground and flattened. In the mold grinding step, the closure component may be completely removed or at least partially remain without being removed. In this case, in case that a part of the closure component remains in the mold grinding step, the closure component may be perforated by a laser process in order to form holes in the inlet port 221 and the outlet port 222.

As illustrated in FIG. 5E, the step of dividing the interposer wafer 4 into the individual interposer packages 2 is performed, and this step refers to a step of dicing the interposer wafer 4.

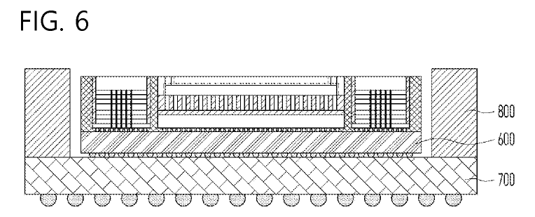

FIG. 6 illustrates a final step of finishing the semiconductor package 1 in the method of manufacturing the semiconductor package according to the embodiment of the present disclosure.

The method of manufacturing the semiconductor package 1 according to the embodiment of the present disclosure may further include a step of mounting the individual interposer packages 2 on the packaging substrate 700, and a step of coupling the lid 300 and the stiffener 800, which is formed on the periphery of the substrate 700 of the semiconductor package 1, by means of the fastening member 900.

That is, as the final step for the semiconductor packaging, a step of mounting the individual interposer packages 2 on the package substrate 700 and coupling the lid 300 and the stiffener 800, which defines an external appearance of the semiconductor package 1, may be performed.

While the present disclosure has been described with reference to the specific embodiments, the specific embodiments are only for specifically explaining the present disclosure, and the present disclosure is not limited to the specific embodiments. It is apparent that the present disclosure may be modified or altered by those skilled in the art without departing from the technical spirit of the present disclosure.

All the simple modifications or alterations to the present disclosure fall within the scope of the present disclosure, and the specific protection scope of the present disclosure will be defined by the appended claims.

What is claimed is:

1. A semiconductor package, in which a plurality of semiconductor chips having different heights are mounted, the semiconductor package comprising:
a fluid flow structure bonded directly to a first semiconductor chip among the plurality of semiconductor chips and formed to allow a fluid to flow therethrough,
wherein a second semiconductor chip, which is greater in thickness than the first semiconductor chip among the plurality of semiconductor chips, is mounted on the semiconductor package.

2. The semiconductor package of claim 1, wherein the fluid flow structure comprises:
a microchannel part comprising a plurality of microchannels through which the fluid flows, the microchannel part bonded directly to the first semiconductor chip; and
a manifold part formed on the microchannel part and configured to distribute the fluid to the microchannels and collect the fluid.

3. The semiconductor package of claim 2, comprising:
a lid formed to cover the plurality of semiconductor chips,
wherein the fluid flow structure communicates with a fluid port formed in the lid and is disposed in a space between the lid and the first semiconductor chip.

4. The semiconductor package of claim 3, wherein the manifold part comprises:
an inlet port through which the fluid is supplied to the microchannels; and
an outlet port through which the fluid is discharged from the microchannels.

5. The semiconductor package of claim 4, wherein the fluid port comprises a first fluid port comprising:
a first fluid supply port configured to supply the fluid to the inlet port; and
a first fluid discharge port configured to collect the fluid from the outlet port.

6. The semiconductor package of claim 5, comprising:
a sealing member formed between the lid and the manifold part and configured to prevent the fluid from leaking and prevent the fluid, which is introduced into the inlet port, and the fluid, which is discharged from the outlet port, from being mixed.

7. The semiconductor package of claim 6, wherein the sealing member comprises:
a first sealing member formed to correspond to an outermost side of the manifold and configured to prevent the fluid from leaking; and
a second sealing member formed to correspond to a boundary between the first fluid supply port and the first fluid discharge port and configured to prevent the fluid, which is introduced into the inlet port, and the fluid, which is discharged from the outlet port, from being mixed.

8. The semiconductor package of claim 1, wherein the fluid flow structure is disposed in a space defined by a difference in height between the first semiconductor chip and the second semiconductor chip.

9. The semiconductor package of claim 5, wherein the fluid port comprises a second fluid port formed to correspond to the second semiconductor chip to cool the second semiconductor chip, and
wherein the second fluid port comprises:
a second fluid supply port through which the fluid is introduced; and
a second fluid discharge port through which the fluid is discharged.

10. The semiconductor package of claim 9, wherein a thermal interface material (TIM) layer is formed between the lid and the second semiconductor chip.

11. The semiconductor package of claim 9, wherein the lid and the second semiconductor chip are coupled by direct bonding.

12. The semiconductor package of claim 9, comprising:
a second fluid flow structure bonded directly to the second semiconductor chip and formed to be in fluid communication with the second fluid port.

13. The semiconductor package of claim 3, further comprising:
a stiffener formed on a periphery of a packaging substrate of the semiconductor package; and
a fastening member configured to couple the lid and the stiffener.

14. A method of manufacturing a semiconductor package in which a plurality of semiconductor chips having different heights are mounted, the method comprising:
a first bonding step of bonding a microchannel part directly to a rear surface of a first semiconductor chip among a plurality of semiconductor chips in a fluid flow structure comprising the microchannel part comprising a plurality of microchannels through which a fluid flows, and a manifold part formed on the microchannel part and configured to distribute the fluid to the microchannels and collect the fluid; and
a second bonding step of flip-chip bonding an upper surface of the first semiconductor chip onto an interposer and mounting a second semiconductor chip, among the plurality of semiconductor chips, on the interposer.

15. The method of claim 14, wherein the first bonding step comprises bonding the microchannel part of the fluid flow structure directly to the rear surface of the first semiconductor chip that is completely diced.

16. The method of claim 14, wherein the first bonding step comprises bonding the microchannel part of the fluid flow structure directly onto a first semiconductor wafer before the first semiconductor chip is diced and then dicing the first semiconductor wafer.

17. The method of claim 16, wherein a method of directly bonding the first semiconductor wafer and the fluid flow structure in the first bonding step couples the first semiconductor wafer and a fluid flow structure wafer, on which the plurality of fluid flow structures are formed, by a wafer-on-wafer method.

18. The method of claim 16, wherein a method of directly bonding the first semiconductor wafer and the fluid flow structure in the first bonding step couples the first semiconductor wafer and the fluid flow structure by a chip-on-wafer method of bonding the fluid flow structure directly to the first semiconductor wafer.

19. The method of claim 14, wherein the second bonding step comprises:
a stage step of disposing the plurality of semiconductor chips on an interposer wafer;
an interposer bonding step of flip-chip bonding the upper surface of the first semiconductor to the interposer wafer and mounting the second semiconductor on the interposer wafer;
a wafer level molding step of covering the upper surface of the interposer wafer and the plurality of semiconductor chips with an epoxy molding compound (EMC);
a mold grinding step of grinding or flattening the epoxy molding compound and exposing the manifold part of the fluid flow structure; and
a step of dividing the interposer wafer into individual interposer packages by dicing the interposer wafer.

20. The method of claim 19, further comprising:
a step of mounting the individual interposer packages on a packaging substrate; and
a step of coupling the lid and a stiffener, which is formed on a periphery of the substrate of the semiconductor package, by means of a fastening member.
